(19) United States
(12) Patent Application Publication
(10) Pub. No.: US 2009/0294991 A1
(43) Pub. Date: Dec. 3, 2009

(54) FLIP-CHIP INTERCONNECTION WITH FORMED COUPLINGS

(75) Inventors: Wojtek Sudol, Andover, MA (US); Martha Wilson, Andover, MA (US)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., Eindhoven (NL)

(21) Appl. No.: 12/306,748

(22) PCT Filed: Jun. 20, 2007
(86) PCT No.: PCT/IB2007/052390

§ 371 Date: Dec. 29, 2008

Related U.S. Application Data
(60) Provisional application No. 60/805,760, filed on Jun. 26, 2006.

(51) Int. Cl. H01L 23/538; H01L 21/60

(52) U.S. Cl. 257/778; 438/108; 257/E23.169; 257/E21.511

(57) ABSTRACT

A flip-chip electrical coupling between first and second electrical components (250, 260). The coupling includes a bump (210) and a pad (220). The bump (210) is electrically coupled to the first electrical component (250). The pad (220) is electrically coupled to the second electrical component (260). The pad (220) is electrically coupled to and dimensioned smaller than a corresponding coupling surface (214) of the bump (210). The pad (220) and bump (210) may be electrically coupled together using an ultrasonic stub bump bonding process, conductive epoxy, etc.

The present system relates to an interconnection method and device that uses a flip-chip type of electrical interconnection with a formed electrical pad connection.

Current state of the art integrated circuits (ICs) are continuously shrinking in size and increasing in complexity. As density of components increases, the system of electrically coupling components has become critical in that the physical interconnections occupy a signification portion of available surface area reducing the ability to position electrical circuitry within this area.

An electrical interconnection technology is known wherein one portion of the interconnection is formed by a contact bump and another portion of the interconnection is formed by a contact pad. The pad facilitates a means of making electrical connection. The bump also provides a means of making an electrical connection but also has a substantial height to provide a physical separation between connecting substrates. Typically, the bump is produced on the surface of the ASIC and the pad is positioned on the bottom of the acoustic element. During the manufacturing process, the bump and pad are brought into contact with each other to form the electrical interconnection. U.S. Pat. No. 6,015,652 incorporated herein by reference as if set out in entirety, discloses a type of such an interconnection system termed “flip-chip bonding” for ICs mounted on a substrate. This typical interconnection system alleviates some of the problems associated with other electrical interconnection systems, yet still occupies much of available surface area that might otherwise be utilized for electronic components. This problem is exacerbated further when the electrical interconnection is made directly to an integrated circuit, such as an application-specific integrated circuit (ASIC).

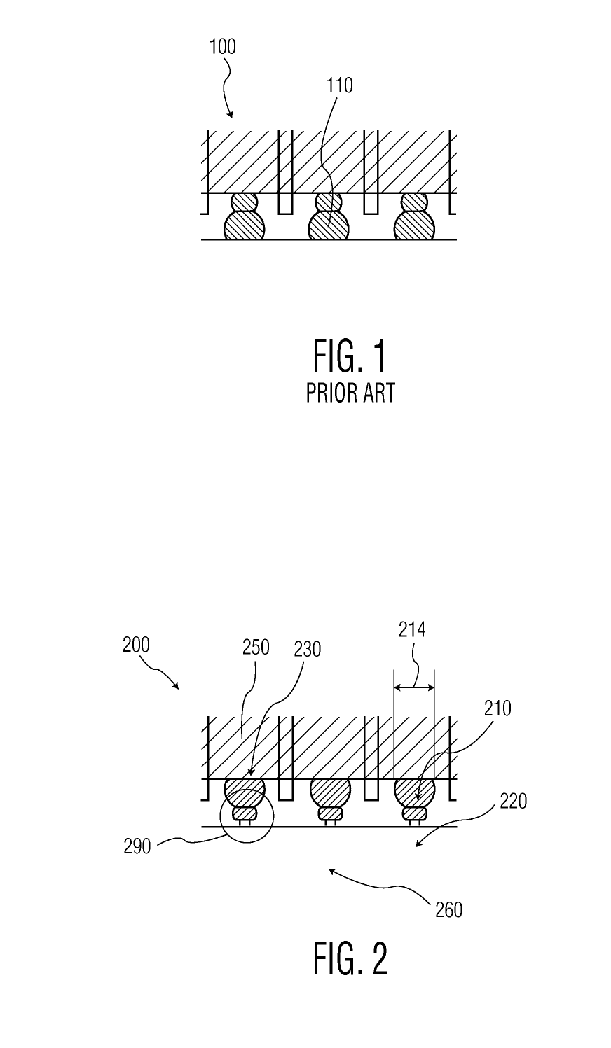

PCT Patent Application WO 2004/052209 incorporated herein by reference as if set out in entirety, discloses a system of electrically coupling an ASIC to a plurality of acoustic elements for the purposes of forming a miniaturized transducer. In the shown system, the bump is electrically coupled to one of the acoustic element or ASIC and the pad is electrically coupled to the other of the acoustic element or ASIC. This system realizes a small electrical package that for example, may be formed to create an ultrasonic transducer that may be utilized for transesophageal, laparoscopic and intra-cardiac examination. Nonetheless, since these products assume a pitch match of the cell circuitry directly under the acoustic element, it is desirable to reduce the pitch further. The current mixed-signal ASIC processes and voltages that are needed for proper operation still limit further reduction of the acoustic element and control circuitry. For example, for a flip-chip interconnection system 100 using stud-shaped bumps 110, such as shown in FIG. 1, positioned on a 185 um pitch array, approximately 40% of the area of the ASIC is not usable for circuitry due to these bumps. The pads or surfaces that electrically interconnect to the bumps are typically larger laterally across a surface that contacts the bump than a contacting surface of the bump. In other words, the bump surface that makes an electrical interconnection with the pad is smaller than a corresponding contacting surface on the pad.

It is an object of the present system to overcome disadvantages and/or make improvements in the prior art. It is an object of the present system to provide ways to reduce the pitch using chip fabrication techniques that are achievable using, for example, typical ASIC technology.

In accordance with the present system, a flip-chip electrical coupling is formed between first and second electrical components. The coupling includes a bump and a pad. The bump is electrically coupled to the first electrical component. The pad is electrically coupled to the second electrical component. The pad is electrically coupled to and dimensioned smaller than a corresponding coupling surface of the bump. In one embodiment, the pad and bump may be electrically coupled together using an ultrasonic stub bump bonding process. In another embodiment the pad and bump may be electrically coupled together using conductive epoxy. The bump may be stud-shaped, ball-shaped, etc.

In the same or another embodiment, the first electrical component may be an acoustic element and/or the second electrical component may be an ASIC. The coupling may be one of a plurality of electrical couplings present in a pitch array of less than 150 um.

The following are descriptions of illustrative embodiments that when taken in conjunction with the following drawings will demonstrate the above noted features and advantages, as well as further ones. In the following description, for purposes of explanation rather than limitation, specific details are set forth such as the particular architecture, interfaces, techniques, etc., for illustration. However, it will be apparent to those of ordinary skill in the art that other embodiments that depart from these specific details would still be understood to be within the scope of the appended claims. Moreover, for the purpose of clarity, detailed descriptions of well-known devices, circuits, and methods are omitted so as not to obscure the description of the present system.

It should be expressly understood that the drawings are included for illustrative purposes and do not represent the scope of the present system. In the accompanying drawings, like reference numbers in different drawings designate similar elements.

FIG. 1 shows a prior art flip-chip interconnection system;

FIG. 2 shows an illustrative cross-section of a flip-chip interconnection in accordance with an embodiment of the present system; and

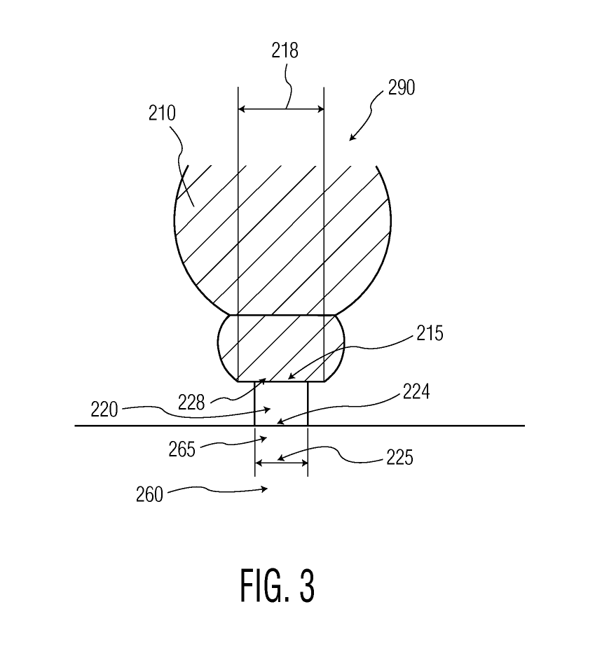

FIG. 3 shows a detailed cross-sectional area section 290 of the illustrative flip-chip interconnection system 200 shown in FIG. 2 in accordance with an embodiment of the present system.

FIG. 2 shows an illustrative cross-section of a flip-chip interconnection system 200 in accordance with an embodiment of the present system. In this embodiment, a high aspect bump 210 is shown in a form of a stud bump that during fabrication is electrically coupled to a de-matching layer surface 230 of an electrical component, such as an acoustic element 250. The bump may be in any form including a ball, stud or other shape that may be suitably applied. The acoustic element may be of a type for generating ultrasonic energy emissions as may be useful in an ultrasonic transducer application.

FIG. 3 shows a detailed cross-sectional area section 290 of the illustrative flip-chip interconnection system 200 shown in FIG. 2 in accordance with an embodiment of the present system. The bump 210 may be fabricated using any fabrication process, such as plating, machining, forming, electro-lithography, wire bonding, or any other fabrication process that may be suitably applied. In one application, the bump 210 height may be in the range of 50-150 um high, such as 100 um high, and have a contacting surface 214 electrically coupled with the acoustic element 250, and having a diameter in the range of 50-120 um, such as 70 um. The height of the bump 210 helps provide a physical separation between connecting substrates, such as the acoustic element 250 and the ASIC 260.

In accordance with an embodiment of the present system, an IC, such as ASIC 260, has contact pads 220, which are electrically coupled to the ASIC 260 through a contacting surface 224 of the pads 220. The electrical coupling may be provided through a contact metallization layer 265 of the ASIC 260 or any other system for providing electrical interconnection between the contact pad 220 and the ASIC 260. In one embodiment, the pads 220 may have a diameter 225 in the range of 10-70 um, such as a diameter of 20 um and a height in the range of 1-30 um, such as a height of 15 um. The pads 220 may be formed by any forming and/or deposition process including electrolysis plating, sputtering, photo-deposition, or other system that may be suitably applied. In one embodiment, the pads 220 may be formed simply utilizing electrolysis plating of gold as may be readily achieved using low-cost metallurgical techniques.

In accordance with the present system, the pad 220 is formed having a small diameter 225 as compared to a contacting surface 215 of the bump 210. For example, the contacting surface 215 may have a diameter 218 in the range of 40-80 um, such as a diameter of 50 um. By forming a relatively small diameter pad 220 on the ASIC 260, a larger portion of the ASIC surface area may be utilized for circuitry as opposed to prior systems. For example, the present system of interconnection may be suitably applied in fine-pitched arrays of 150 um and less. In a further embodiment, electrical coupling between the bump 210 contacting surface 215 and the pad 220 contacting surface 228 may be brought about using low temperature and pressure bonding techniques, such as ultrasonic stub bump bonding. This technique has the added advantage that since low pressure is utilized between the bonding surfaces (e.g., between the bump and pad), the area of the ASIC 260 below the pad 220 (e.g., below the top metallization layer 265 of the ASIC 260) may be utilized for circuitry and accordingly, may result in more useable area of the ASIC than in prior systems. In another embodiment the pad 220 and the bump 210 may be electrically coupled together using conductive epoxy.

In addition, it should be readily appreciated that although in the illustrative embodiment, three acoustic elements 250 are shown with three interconnection systems (e.g., bump 210 and pad 220), more or less may be utilized depending on a desired application. The acoustic elements 250 may be of any type and configuration including a configuration that facilitates 3-dimensional (3-D) imaging such as may be utilized for a 3-D ultrasonic imaging application and/or matrix transducer configurations.

Of course, it is to be appreciated that any one of the above embodiments or processes may be combined with one or with one or more other embodiments or processes to provide even further improvements in accordance with the present system.

Finally, the above-discussion is intended to be merely illustrative of the present system and should not be construed as limiting the appended claims to any particular embodiment or group of embodiments. Thus, while the present system has been described in particular detail with reference to specific exemplary embodiments thereof, it should also be appreciated that numerous modifications and alternative embodiments may be devised by those having ordinary skill in the art without departing from the broader and intended spirit and scope of the present system as set forth in the claims that follow. Accordingly, the specification and drawings are to be regarded in an illustrative manner and are not intended to limit the scope of the appended claims.

In interpreting the appended claims, it should be understood that:

a) the word “comprising” does not exclude the presence of other elements or acts than those listed in a given claim;

b) the word “a” or “an” preceding an element does not exclude the presence of a plurality of such elements;

c) any reference signs in the claims do not limit their scope;

d) several “means” may be represented by the same item or hardware or software implemented structure or function;

e) any of the disclosed elements may be comprised of hardware portions (e.g., including discrete and integrated electronic circuitry), software portions (e.g., computer programming), and any combination thereof;

f) hardware portions may be comprised of one or both of analog and digital portions;

g) any of the disclosed devices or portions thereof may be combined together or separated into further portions unless specifically stated otherwise; and

h) no specific sequence of acts or steps is intended to be required unless specifically indicated.

1. A flip-chip electrical coupling between first and second electrical components (250, 260), the coupling comprising:
a bump (210) comprising first and second electrical coupling surfaces (214, 215), wherein the first coupling surface (214) of the bump (210) is electrically coupled to the first electrical component (250); and
a pad (220) comprising first and second electrical coupling surfaces (224, 228), wherein the first coupling surface (224) of the pad (220) is electrically coupled to the second electrical component (260) and the second electrical coupling surface (228) of the pad (220) is electrically coupled to and dimensioned smaller than the second electrical coupling surface (215) of the bump (210).

2. The coupling of claim 1, wherein the bump (210) is a stud-shaped bump.

3. The coupling of claim 1, wherein the bump (210) is a ball-shaped bump.

4. The coupling of claim 1, wherein the bump (210) is configured with a bump height in the range of 50-150 um.

5. The coupling of claim 1, wherein the first coupling surface (214) of the bump has a diameter in the range of 50-120 um.

6. The coupling of claim 1, wherein the pad (220) is configured having a diameter in the range of 10-70 um.

7. The coupling of claim 1, wherein the first electrical component (250) is an acoustic element.

8. The coupling of claim 1, wherein the second electrical component (260) is an ASIC.

9. The coupling of claim 8, wherein the ASIC is configured having circuitry positioned below the pad.

10. The coupling of claim 1, wherein the coupling is configured as one of a plurality of electrical couplings in a pitch array of less than 150 um.

11. A method for forming a flip-chip electrical coupling between first and second electrical components (250, 260), the process comprising the acts of:
coupling a bump portion (210) to the first electrical component (250);
coupling a pad portion (220) to the second electrical component (260); and
coupling the bump portion (210) to the pad portion (220), wherein a surface (228) of the pad portion (220) that is coupled to the bump portion (210) is dimensioned smaller than a corresponding coupling surface (215) of the bump portion (210).

12. The method of claim 11, comprising the act of forming the bump portion (210) as a stud-shaped bump portion.

13. The method of claim 11, comprising the act of forming the bump portion (210) having a bump height in the range of 50-150 um and a surface (214) coupled to the first electrical component (250) having a diameter in the range of 50-120 um.

14. The method of claim 11, comprising the act of forming the pad portion (220) having a diameter in the range of 10-70 um.

15. The method of claim 11, wherein the act of coupling the bump portion (210) to the pad portion (220) is performed using a low temperature and low bonding pressure coupling technique.

16. The method of claim 15, wherein the low temperature and low bonding pressure coupling technique is ultrasonic stub bump bonding.

17. The method of claim 11, comprising the act of forming the flip chip electrical coupling as one of a plurality of electrical couplings formed within a pitch array of less than 150 um.

18. The method of claim 11, wherein the act of coupling the bump portion (210) to the pad portion (220) is performed using conductive epoxy.
